(19) United States
(12) Patent Application Publication
(10) Pub. No.: US 2010/0144095 A1
(43) Pub. Date: Jun. 10, 2010

(54) METHOD OF MANUFACTURING SEMICONDUCTOR DEVICE IN WHICH BOTTOM SURFACE AND SIDE SURFACE OF SEMICONDUCTOR SUBSTRATE ARE COVERED WITH RESIN PROTECTIVE FILM

(75) Inventors: Taisuke KOROKU, Sagamihara-shi (JP); Osamu Okada, Hamura-shi (JP); Osamu Kuwabara, Tokyo (JP); Junji Shiota, Hamura-shi (JP); Nobumitsu Fujii, Ome-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/632,006

(22) Filed: Dec. 7, 2009

(30) Foreign Application Priority Data
Dec. 10, 2008 (JP) 2008-314022

(51) Int. Cl. H01L 21/50

(52) U.S. Cl. 438/113; 257/E21.499

(57) ABSTRACT

First, a trench formed in parts of a semiconductor wafer, a sealing film and others corresponding to a dicing street and both sides thereof. In this state, the semiconductor wafer is separated into silicon substrates by the formation of the trench. Then, a resin protective film is formed on the bottom surface of each silicon substrate including the inner part of the trench. In this case, the semiconductor wafer is separated into the silicon substrates. However, a support plate is affixed to the upper surfaces of the columnar electrode and the sealing film via an adhesive layer. Therefore, when the resin protective film is formed, it is possible to prevent the entirety including the separated silicon substrates from being easily warped.

### CROSS-REFERENCE TO RELATED APPLICATIONS

This application is based upon and claims the benefit of priority from prior Japanese Patent Application No. 2008-314022, filed Dec. 10, 2008, the entire contents of which are incorporated herein by reference.

### BACKGROUND OF THE INVENTION

1. Field of the Invention

The present invention relates to a method of manufacturing a semiconductor device in which the bottom surface and side surface of a semiconductor substrate are covered with a resin protective film.

2. Description of the Related Art

A device which is called a chip-size package (CSP) is known from Published Japanese Patent No. 4103896. In this semiconductor device, a plurality of wiring lines are provided on the upper surface of an insulating film disposed on a semiconductor substrate. A columnar electrode is provided on the upper surface of a connection pad portion of the wiring line. A sealing film is provided on the upper surface of the insulating film including the wiring lines so that the upper surface of this sealing film is flush with the upper surface of the columnar electrode. A solder ball is provided on the upper surface of the columnar electrode. In this case, in order to prevent the exposure of the lower surface and side surface of the semiconductor substrate, the lower surface and side surface of the semiconductor substrate are covered with a resin protective film.

Meanwhile, in Published Japanese Patent No. 4103896, an assembly in which an insulating film, wiring lines, columnar electrodes and a sealing film are formed is prepared on the upper side of a semiconductor substrate in a wafer state (hereinafter referred to as a semiconductor wafer). Then, the semiconductor wafer is turned upside down. Then, a trench having a predetermined width is formed partway through the sealing film by half-cut (cutting halfway) between semiconductor device formation regions on the bottom side (the surface opposite to the surface in which the sealing film and others are formed) of the semiconductor wafer. In this state, the semiconductor wafer is separated into semiconductor substrates by the formation of the trench.

Furthermore, a resin protective film is formed on the bottom surfaces of the semiconductor substrates including the inner part of the trench. Then, the entirety including the semiconductor substrates is turned upside down. Then, solder balls are formed on the upper surfaces of the columnar electrodes. Then, the sealing film and the resin protective film are cut in the center of the width direction of the trench. Consequently, a semiconductor device having a structure in which the bottom surface and side surface of the semiconductor substrate are covered with the resin protective film obtained.

However, in Published Japanese Patent. No. 4103896, after the trench is formed partway through the sealing film by half-cut on the bottom side of the semiconductor wafer turned upside down, the resin protective film is simply formed on the bottom surfaces of the semiconductor substrates including the inner part of the trench. That is, the resin protective film is simply formed in a condition where the semiconductor wafer is separated into the semiconductor substrates by the formation of the trench. Therefore, strength in the half-cut step and the subsequent steps decreases, and the entirety including the semiconductor substrates is warped to a relatively great extent. This disadvantageously causes difficulty in maintaining the quality and in handling in each step.

It is therefore an object of this invention to provide a semiconductor device manufacturing method which can prevent the entirety including semiconductor substrates from being easily warped during the formation of a resin protective film for protecting the semiconductor substrates.

### BRIEF SUMMARY OF THE INVENTION

According to a first aspect of the present invention, there is provided a semiconductor device manufacturing method which comprises preparing an assembly having an insulating film formed on one surface of a semiconductor wafer where an integrated circuit is formed, an electrode connection pad portion formed on the insulating film in such a manner as to be connected to the integrated circuit, an external connection bump electrode formed on the electrode connection pad portion, and a sealing film formed around the external connection bump electrode; affixing a support plate having a large number of pores to the external connection bump electrode and the sealing film via an adhesive layer; forming a trench reaching an intermediate position of the thickness of the sealing film on the bottom side of the semiconductor wafer in parts corresponding to a dicing street and both sides thereof; forming a resin protective film on the bottom surface of the semiconductor wafer including the inner part of the trench; infiltrating a detachment solution from the pores in the support plate to dissolve and remove the adhesive layer, and thereby separating the support plate from the external connection bump electrode and the sealing film; and cutting the sealing film and the resin protective film in a width smaller than the width the trench, wherein a plurality of semiconductor devices are obtained in which the resin protective film is formed on a side surface ranging from the side surface of the semiconductor substrate to the intermediate position of the sealing film and on the bottom surface of the semiconductor substrate.

According to this invention, a resin protective film is formed on the bottom surface of a semiconductor wafer (semiconductor substrates) including the inner part of a trench in a condition where a support plate is affixed to an external connection bump electrode and a sealing film. Thus, it is possible to prevent the entirety including the semiconductor substrates from being easily warped during the formation of the resin protective film for protecting the semiconductor substrates.

### BRIEF DESCRIPTION OF THE SEVERAL VIEWS OF THE DRAWING

FIG. 1 is a sectional view of one example of a semiconductor device manufactured by a manufacturing method of this invention;

FIG. 2 is a sectional view of an initially prepared assembly in one example of the method of manufacturing the semiconductor device shown in FIG. 1;

FIG. 3 is a sectional view of a step following FIG. 2;

FIG. 4 is a sectional view of a step following FIG. 3;

FIG. 5 is a sectional view of a step following FIG. 4;

FIG. 6 is a sectional view of a step following FIG. 5;

FIG. 7 is a sectional view of a step following

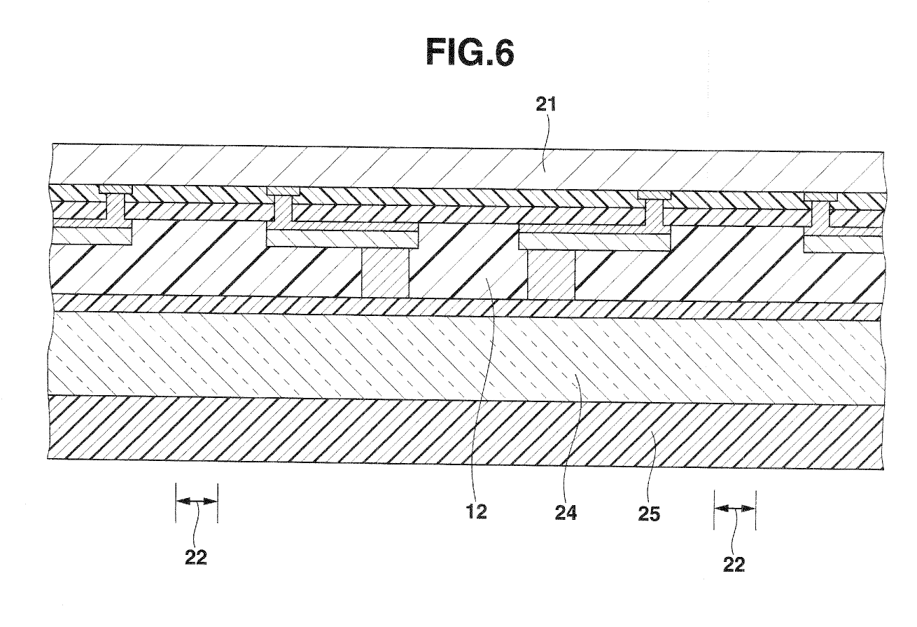

FIG. 6;

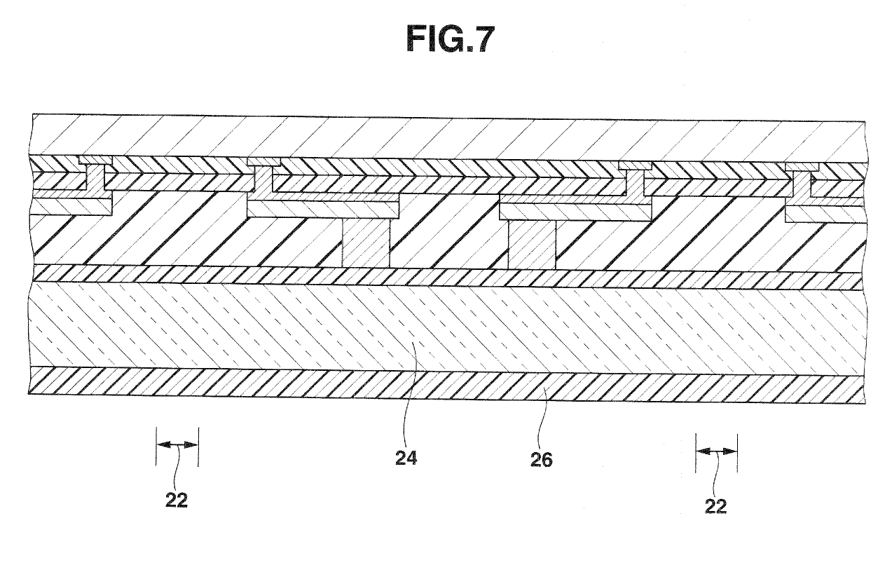

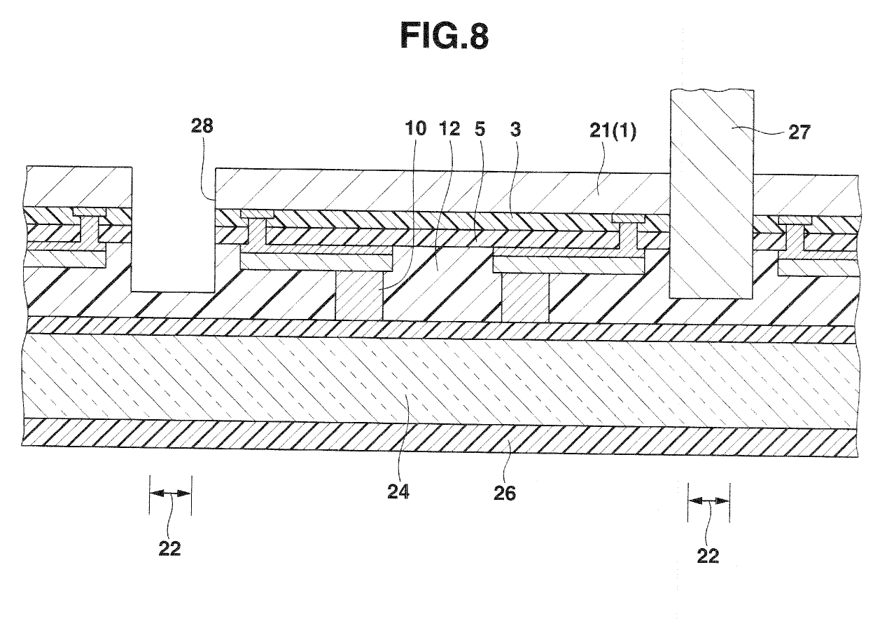

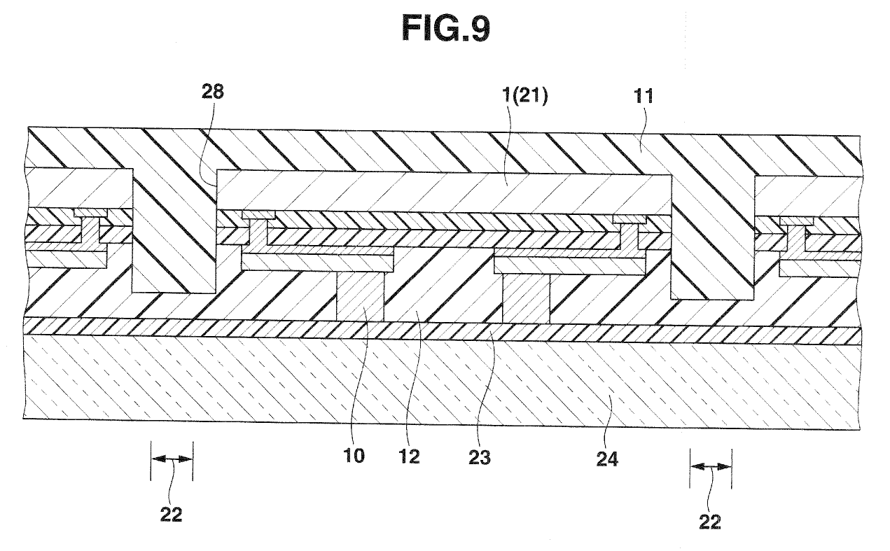

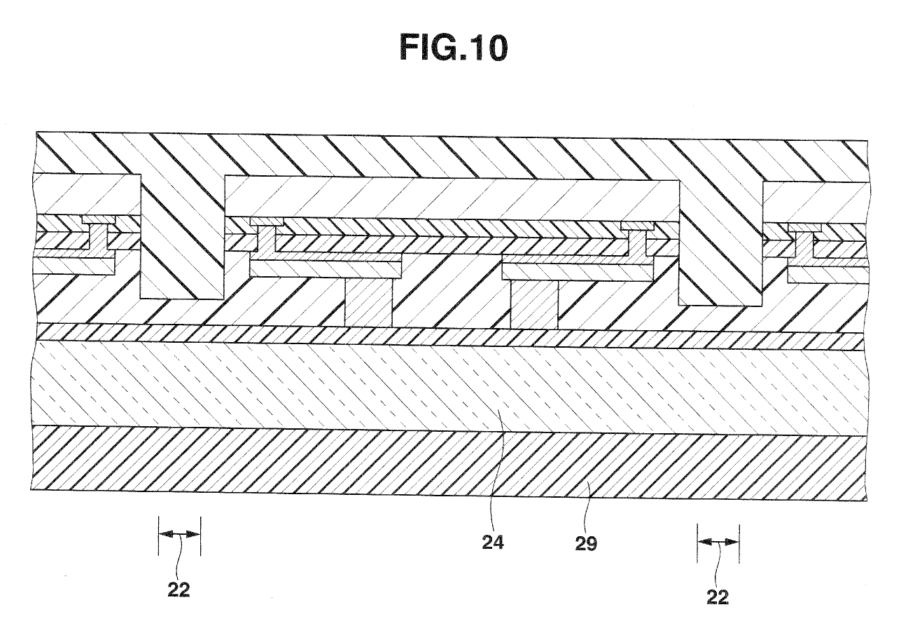

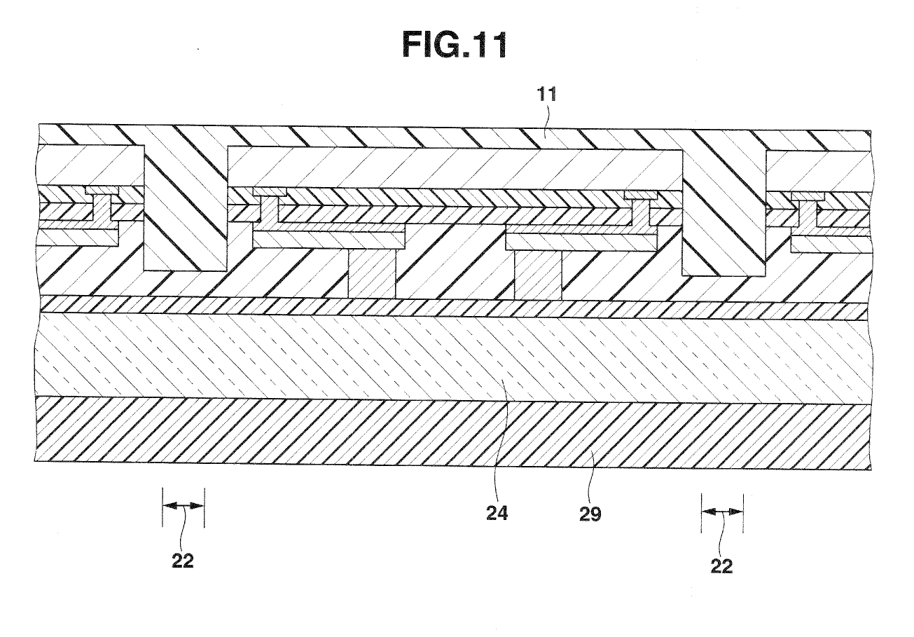

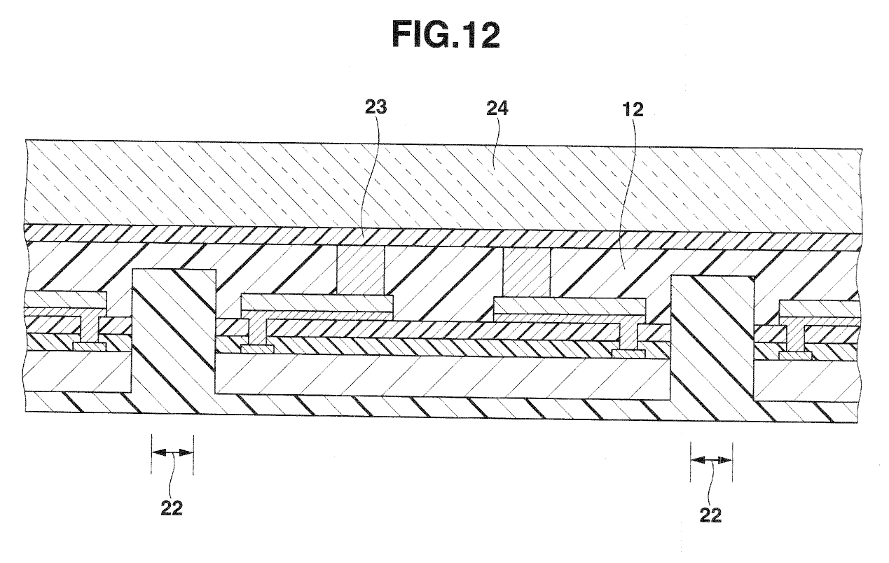

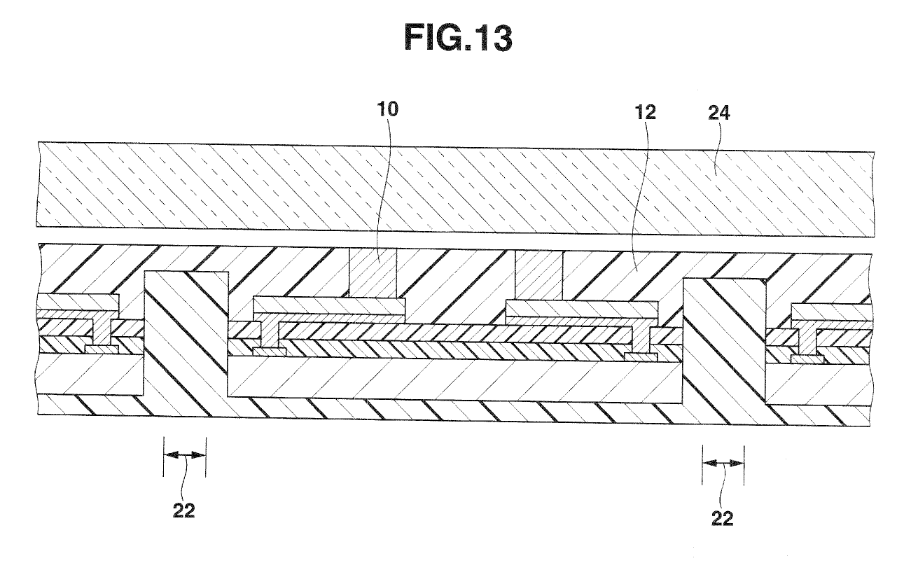

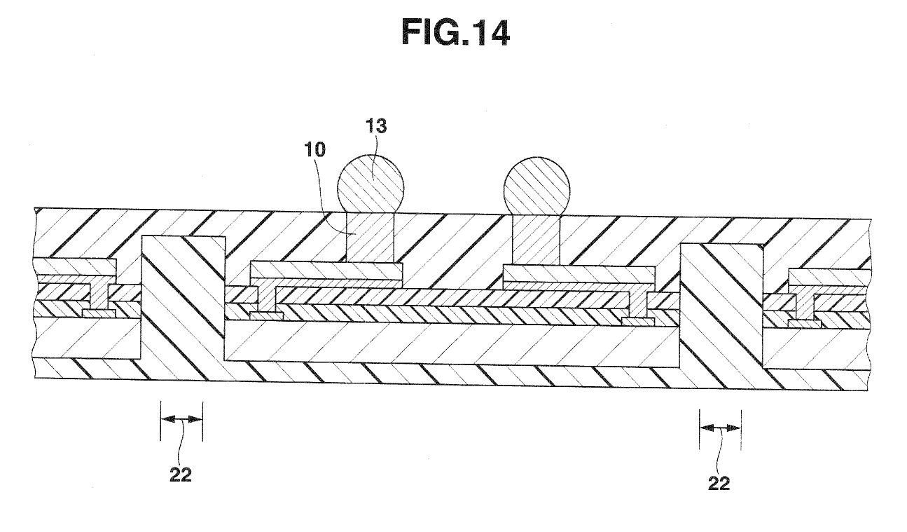

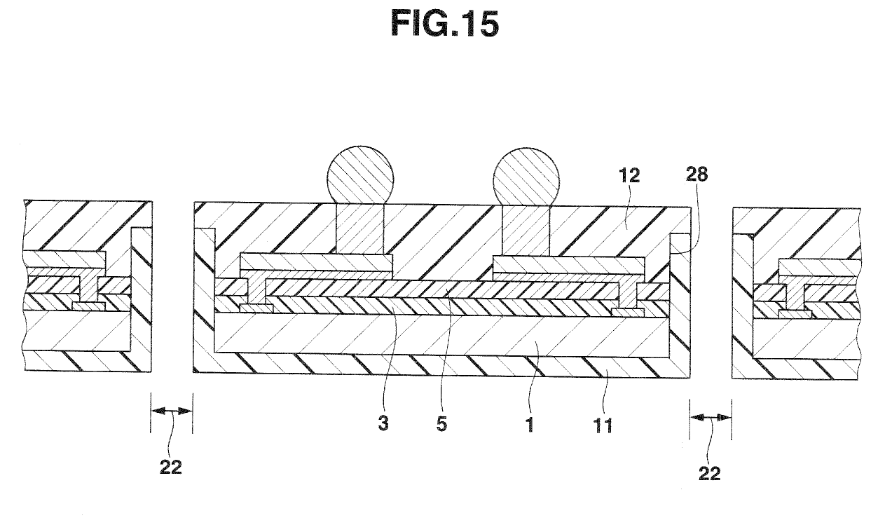

FIG. 8 is a sectional view of a step following FIG. 7;

FIG. 9 is a sectional view of a step following FIG. 8;

FIG. 10 is a sectional view of a step following FIG. 9;

FIG. 11 is sectional view of a step following FIG. 10;

FIG. 12 is a sectional view of a step following

FIG. 11;

FIG. 13 is a sectional view of a step following FIG. 12;

FIG. 14 is a sectional view of a step following FIG. 13; and

FIG. 15 is a sectional view of a step following FIG. 14.

### DETAILED DESCRIPTION OF THE INVENTION

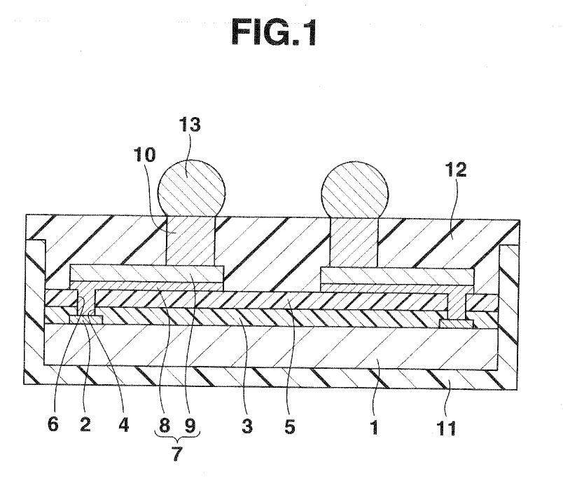

FIG. 1 shows a sectional view of one example of a semiconductor device manufactured by a manufacturing method of this invention. This semiconductor device is generally called a CSP, and includes a silicon substrate (semiconductor substrate) 1. Elements (not shown) constituting an integrated circuit having a predetermined function, such as a transistor, a diode, a register and a condenser, are formed on the upper surface of the silicon substrate 1. Connection pads 2 made of, for example, an aluminum-based metal and connected to the elements of the integrated circuit are provided in the peripheral part of the upper surface of the silicon substrate 1. Although two connection pads 2 are only shown, a large number of connection pads 2 are actually arranged on the peripheral part of the upper surface of the silicon substrate 1.

A passivation film (insulating film) 3 of, for example, silicon oxide is provided on the upper surfaces of the silicon substrate 1 except for the center of the connection pad 2. The center of the connection pad 2 is exposed via an opening 4 provided in the passivation film 3. A protective film (insulating film) 5 of, for example, a polyimide-based resin is provided on the upper surface of the passivation film 3. An opening 6 is provided in a part of the protective film 5 corresponding to the opening 4 of the passivation film 3.

A wiring line 7 is provided on the upper surface of the protective film 5. The wiring line 7 has a two-layer structure composed of a foundation metal layer 8 of, for example, copper provided on the upper surface of the protective film 5, and an upper metal layer 9 of copper provided on the upper surface of the foundation metal layer 8. One end of the wiring line 7 is connected to the connection pad 2 via the openings 4, 6 of the passivation film 3 and the upper protective film 5. A columnar electrode (external connection Pump electrode) 10 made of copper is provided on the upper surface of a connection pad portion (electrode connection pad portion) of the wiring line 7.

A resin protective film 11 made of, for example, an epoxy resin is provided on the bottom surface of the silicon substrate 1 and on the side surfaces of the silicon substrate 1, the passivation film 3 and the upper protective film 5. In this case, the upper part of the resin protective film 11 provided on the side surfaces of the silicon substrate 1, the passivation film 3 and the upper protective film 5 projects straight upward from the upper surface of the upper protective film 5. In this state, the lower surface of the silicon substrate 1 and the side surfaces of the silicon substrate 1, the passivation film 3 and the upper protective film 5 are covered with the resin protective film 11.

A sealing film 12 made of, for example, an epoxy resin is provided on the upper surface of the upper protective film 5 including the wiring line 7 and on the upper surface of the resin protective film 11 therearound. The columnar electrode 10 is provided so that its upper surface is flush with or several μm lower than the upper surface of the sealing film 12. A solder ball 13 is provided on the upper surface of the columnar electrode 10.

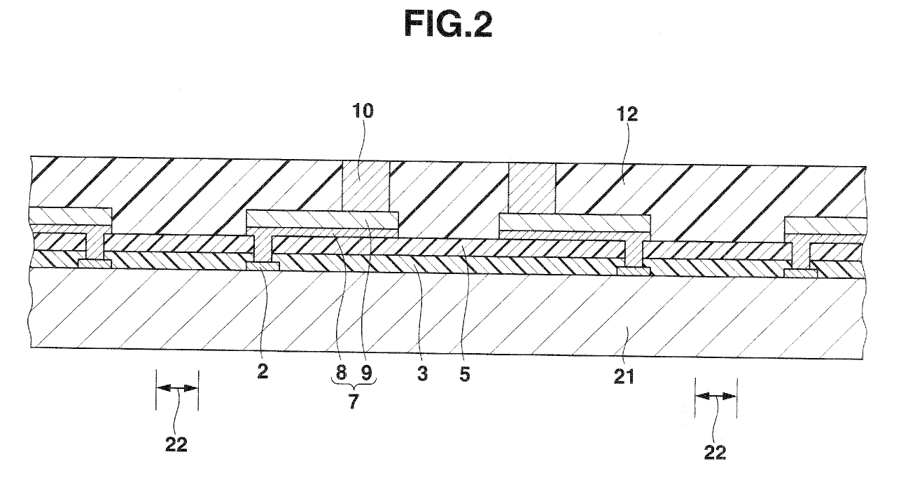

Next, one example of a method of manufacturing this semiconductor device is described. First, as shown in FIG. 2, an assembly in which a connection pad 2, a passivation film 3, a protective film 5, a wiring line 7 having a two-layer structure composed of a foundation metal layer 8 and an upper metal layer 9, columnar electrode 10 and a sealing film 12 are provided is prepared on a silicon substrate in a wafer state (hereinafter referred to as a semiconductor wafer 21). Such a method of manufacturing the semiconductor wafer 21 is already known. For details, see, for example, FIG. 2 to FIG. 7 and relevant parts in the specification of Japanese Patent No. 3955059.

In this case, the thickness of the semiconductor wafer 21 is greater to some degree than the thickness of the silicon substrate 1 shown in FIG. 1. Moreover, the upper surface of the sealing film 12 including the upper surface of the columnar electrode 10 is planar. Here, a zone indicated by the sign 22 in FIG. 2 is a zone corresponding to the dicing street.

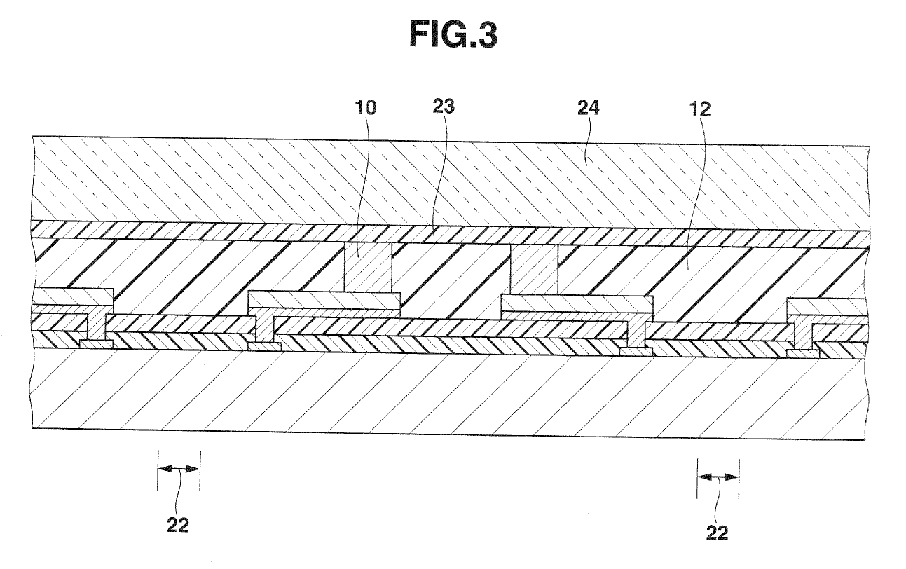

Now, when the assembly shown in FIG. 2 is prepared, a support plate 24 is affixed to the upper surfaces of the columnar electrode 10 and the sealing film 12 via an adhesive layer 23, as shown in FIG. 3. In this case, the adhesive layer 23 is preferably a nonaqueous high-molecular compound, in particular, an acrylic resin, in terms of heat resisting properties.

However, the adhesive layer 23 is not limited thereto, and, for example, a novolak resin, an epoxy resin or an amide resin can be used for the adhesive layer 23. One example of the material of the adhesive layer 23 can be seen in Jpn. Pat. Appln. KOKAI Publication No. 2005-191550. The support plate 24 is, for example, circular glass plate, metal plate or ceramic plate which has a large number of pores (not shown) and which is slightly larger than the semiconductor wafer 21. The thickness of the support plate 24 is, for instance, 0.7 to 1.0 mm. A small hole opens in all aspects of the support plate 24 at uniform intervals, and is a penetration hole that penetrates through the thickness direction.

Furthermore, a liquid adhesive agent for forming the adhesive layer 23 on the upper surfaces of the columnar electrode 10 and the sealing film 12 is first applied by, for example, a spin coat method. Then, a solvent is extracted from the adhesive layer 23 by prebaking to cure and dry the adhesive layer 23. Then, the support plate 24, for example, the glass plate having a large number of pores (not shown), is heated in a vacuum and thereby affixed to the upper surface of the adhesive layer 23. The support plate 24, for example, the glass plate, is affixed in a vacuum to prevent air from being trapped between the support plate 24 and the adhesive layer 23.

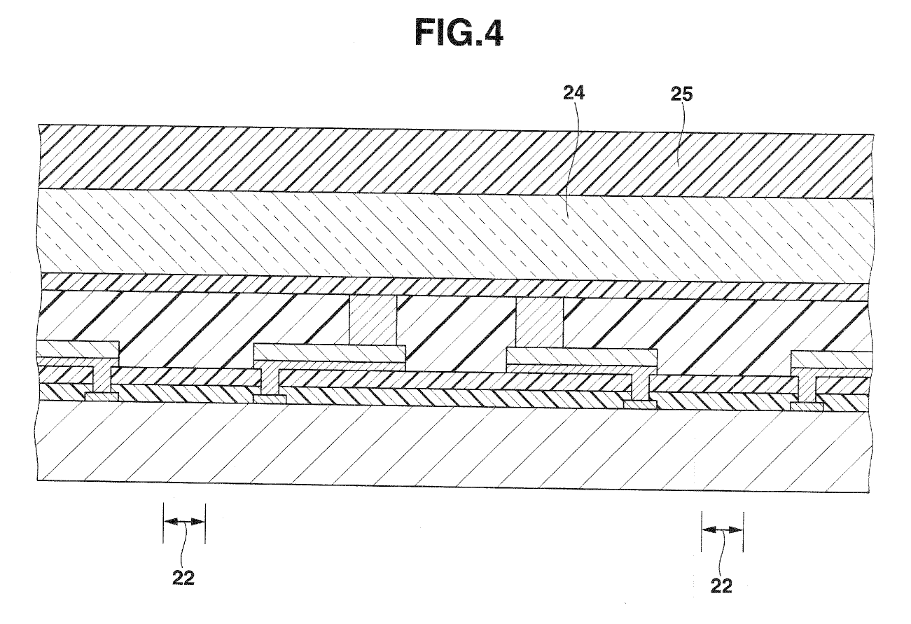

Then, as shown in FIG. 4, a first protective tape 25 for covering the large number of pores is affixed to the upper surface of the support plate 24. A base material attached with an adhesive material such as acrylate-based material can be used as the first protective tape 25. The base material can be selected from polyolefin-based material such as polyethylene, PET (polyethylene terephthalate) such as polyethylene, and EVA (ethylene vinyl acetate copolymer).

However, because the first protective tape 25 is used only to prevent from infiltration of the grinding water used when the silicon at the bottom of the semiconductor wafer 21 is ground, it is not one limited to this.

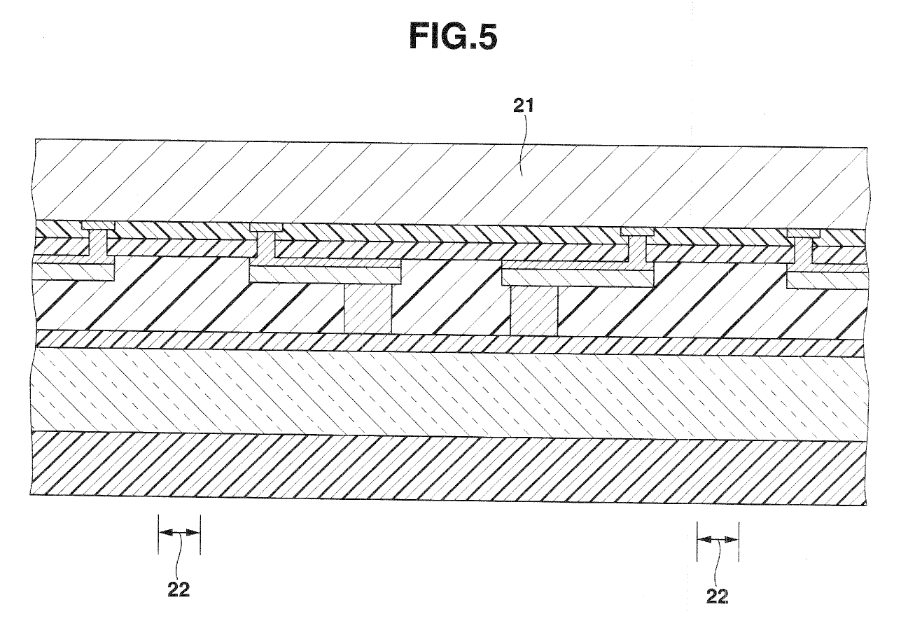

The function of the first protective tape 25 will be described later. Then, the assembly shown in FIG. 4 is turned upside down to turn up the bottom surface (the surface opposite to the surface in which the sealing film 12 and others are formed) of the semiconductor wafer 21. Then, it becomes as shown in FIG. 5.

It puts on the stage (not shown), it is vacuum adsorbed to fix. Then, as shown in FIG. 6, the bottom side of the semiconductor wafer 21 is properly ground using a grindstone (not shown) to properly reduce the thickness of the semiconductor wafer 21.

In this case, water is used to cool the removal of the cutting down rubbish and the whetstone. Because the cutting down rubbish etc. of silicon have mixed, this grinding water is not clean. Moreover, because it is not possible to wash it easily when the cutting down rubbish invades a small hole once, the detachment solution that uses for pealing the support plate 24 off when detachment is made dirty, and it is mounted on the sealing film 12.

However, In this case, as the first protective tape 25 is affixed to the lower surface of the support plate 24, water used during the grinding never comes into the pores in the support plate 24. Therefore, because the cutting down rubbish enters a small hole of the support plate 24, and a small hole is not blocked, the support plate 24 can be recycled. Then, the first protective tape 25 is detached from the lower surface of the support plate 24. In addition, the support plate 24 may be affixed after the thickness of the semiconductor wafer 21 is properly reduced.

Then, as shown in FIG. 7, the lower surface of the support plate 24 is affixed to the upper surface of a dicing tape 26. As for the dicing, the tape doesn't peel off easily compared with the case to grind the bottom side of the semiconductor wafer 21 with the grinding whetstone. Therefore, the thickness of the paste of the dicing tape 26 is 1/10 or less of the thickness of the paste of the first protective tape 25. As for the dicing tape 26, adhesive power is weaker than the first protective tape 25, and the thickness of the tape is also thinner as the result. Then, as shown in FIG. 8, a blade 27 is prepared. This blade 27 is a disk-shaped grindstone. The sectional shape of its edge is substantially U-shaped, and its thickness is greater to some degree than the width of the dicing street 22.

Furthermore, this blade 27 is used to form a trench 28 in parts of the semiconductor wafer 21 corresponding to the dicing street 22 and both sides thereof, the passivation film 3, the protective film 5 and the sealing film 12. In this case, the depth of the trench 28 extends partway in the sealing film 12, and is, for example, half or more, preferably one-third or more than the thickness of the sealing film 12. In this state, the semiconductor wafer 21 is separated into the semiconductor substrates 1 by the formation of the trench 28. Then, the support plate 24 is detached from the upper surface of the dicing tape 26. In addition, in this step, the use of a dicing machine for the half-cut enables processing without affixing the dicing tape.

Then, as shown in FIG. 9, a thermosetting resin such as an epoxy resin is applied onto the bottom side of the silicon substrate 1 including the inner part of the trench 28 by, for example, a spin coat method or a screen printing method. The thermosetting resin is cured to form the resin protective film 11. The cu mg temperature ranges between 150 and 250° C., and the processing time is about one hour. In this case, the semiconductor wafer 21 is separated into the silicon substrates 1. However, the support plate 24 is affixed to the lower surfaces of the columnar electrode 10 and the sealing film 12 via the adhesive layer Therefore, when the resin protective film 11 of thermosetting resin such as epoxy resin is applied and cured, it is possible to prevent the entirety including the separated silicon substrates 1 from being easily warped, and it is also possible to prevent any difficulty from being caused in the subsequent steps by the warping.

Then, as shown in FIG. 10, a second protective tape 29 for covering the large number of pores is affixed to the lower surface of the support plate 24. The function of the second protective tape 29 will be described later. Then, as shown in FIG. 11, the upper side of the resin protective film 11 is properly ground using a grindstone (not shown) to properly reduce the thickness of the resin protective film 11 and to planarize the upper surface of the resin protective film 11. In this case, as the second protective tape 29 is affixed to the lower surface of the support plate 24, water used during the grinding never comes into the pores in the support plate 24. In addition, this grinding step is performed to further reduce the thickness of the semiconductor device.

Then, the second protective tape 29 is detached from the lower surface of the support plate 24, and the entirety is turned upside down to turn up the surface of the silicon substrate 1 where the sealing film 12 and others are formed, as shown in FIG. 12. Then, the assembly shown in FIG. 12 is immersed in a detachment solution of, for example, a low-molecular alcohol or propyleneglycol monomethylether acetate methoxypropyl acetate (propyleneglycol monomethylether acetate) (PGMEA), or the detachment solution of the above-mentioned material is sprayed from the upper side of the support plate 24. Thus, the detachment solution infiltrates the pores in the support plate 24 and reaches the adhesive layer 23, so that the adhesive layer 23 is dissolved and removed. As shown in FIG. 13, a space is formed between the support plate 24, the columnar electrode 10 and the sealing film 12, and the support plate 24 is separated from the upper surfaces of the columnar electrode 10 and the sealing film 12. Then, the upper surfaces of the columnar electrode 10 and the sealing film 12 are cleaned to remove residues on the adhesive layer 23.

Then, as shown in FIG. 14, a solder ball 13 is formed on the upper surface of the columnar electrode 10. In this case, if a burr and an oxide film are formed on the upper surface of the columnar electrode 10, the upper surface of the columnar electrode 10 is etched several μm to remove the burr and oxide film. Then, as shown in FIG. 15, the sealing film 12 and the resin protective film 11 are cut along the dicing street 22 in the center of the trench 28. In this case, a blade having the same width as the width of the dicing street 22 is used. Therefore, as shown in FIG. 15, the sealing film 12 is cut so that its side surface is formed to extend from the intermediate position of the resin protective film 11 which is provided on the side surfaces of the silicon substrate 1, the passivation film 3, the protective film 5 and the sealing film 12 up to the intermediate position of the sealing film 12. Consequently, as shown in FIG. 1, a plurality of semiconductor devices having a structure in which the bottom surface and side surface of the silicon substrate 1 are covered with the resin protective film 11 are obtained.

What is claimed is:

1. A semiconductor device manufacturing method comprising:
preparing an assembly having an insulating film formed on one surface of a semiconductor wafer where an integrated circuit is formed, an interconnect formed on the insulating film in such a manner as to be connected to the integrated circuit, an external connection bump electrode formed on the electrode connection pad portion of the interconnect, and a sealing film formed around the external connection bump electrode;
affixing a support plate having a large number of pores to the external connection bump electrode and the sealing film via an adhesive layer;
forming a trench reaching an intermediate position of the thickness of the sealing film on the bottom side of the semiconductor wafer in parts corresponding to a dicing street and both sides thereof;
forming a resin protective film on the bottom surface of the semiconductor wafer including the inner part of the trench;
infiltrating a detachment solution from the pores in the support plate to dissolve and remove the adhesive layer, and thereby separating the support plate from the external connection bump electrode and the sealing film; and
cutting the sealing film and the resin protective film in a width smaller than the width of the trench.

2. The semiconductor device manufacturing method according to claim 1, wherein the support plate is affixed to the adhesive layer while being heated in a vacuum.

3. The semiconductor device manufacturing method according to claim 1, wherein the bottom side of the semiconductor wafer is ground to reduce the thickness of the semiconductor wafer after or before the support plate is affixed.

4. The semiconductor device manufacturing method according to claim 3, further comprising affixing a protective tape to the support plate before the semiconductor wafer is ground, and detaching the protective tape after the semiconductor wafer is ground.

5. The semiconductor device manufacturing method according to claim 1, further comprising grinding the upper side of the resin protective film to reduce the thickness of the resin protective film and planarize the upper surface of the resin protective film, after the resin protective film is formed.

6. The semiconductor device manufacturing method according to claim 5, further comprising affixing another protective tape to the support plate before the esin protective film is ground, and detaching the another protective tape after the resin protective film is ground.

7. The semiconductor device manufacturing method according to claim 1, wherein the adhesive layer is a nonaqueous high-molecular compound.

8. The semiconductor device manufacturing method according to claim 7, wherein the detachment solution is a low-molecular alcohol or propyleneglycol monomethylether acetate (PGMEA).

9. The semiconductor device manufacturing method according to claim 1, further comprising forming a solder ball on the external connection bump electrode after the support plate is separated from the external connection bump electrode and the sealing film.

10. The semiconductor device manufacturing method according to claim 9, wherein the external connection bump electrode is a columnar electrode formed on the electrode connection pad portion.
